(19) United States
(12) Patent Application Publication
(10) Pub. No.: US 2011/0233605 A1
(43) Pub. Date: Sep. 29, 2011

(54) Semiconductor power device layout for stress reduction

(75) Inventor: Fu-Yuan Hsieh, Banciao City (TW)

(73) Assignee: FORCE MOS TECHNOLOGY CO. LTD., Banciao City (TW)

(21) Appl. No.: 12/659,956

(22) Filed: Mar. 26, 2010

(51) Int. Cl. H01L 29/739; H01L 29/78

(52) U.S. Cl. 257/139; 257/330; 257/E29.262; 257/E29.198

(57) ABSTRACT

A semiconductor power device layout with stripe cell structures is disclosed. The inventive structure applies horizontal gate trenches array and vertical gate trenches array alternatively arranged in single device (one or two directions) to balance out the stress caused from one direction. Furthermore, the inventive semiconductor power device provides gate connection trenches connecting to vertical gate trenches and/or horizontal trenches to reduce gate resistance Rg when gate trench length is long.

### FIELD OF THE INVENTION

This invention relates generally to the cell structure and device configuration of semiconductor power devices such as trench MOSFET (Metal Oxide Semiconductor Field Effect Transistor), IGBT (Insulating Gate Bipolar Transistor) and super-junction MOSFET. More particularly, this invention relates to an improved trench MOSFET layout for stress reduction.

### BACKGROUND OF THE INVENTION

It is well known that a trench MOSFET is designed to have gate trenches with stripe cell structures in order to get low Qgd for high switching speed, and further to make Qgd/Qgs<1 for prevention of short through issue in DC/DC conversion applications. However, this kind of trench semiconductor power devices disclosed in prior art is encountering a hazardous problem of high stress on die caused by arranging the gate trenches only in one direction. The die stress is higher when the gate trenches are deeper or the die area is bigger as result of doped poly filled into the gate trenches.

FIG. 1 shows conventional layout of a trench MOSFET with stripe cell structures having a plurality of horizontal gate trenches 105 only in horizontal direction. Termination area 101 is formed around the whole device configuration with first-gate-runner-metal 102 nearby as metal field plate. A plurality of second-gate-runner-metal 103 is formed along vertical direction; in the meanwhile, gate pad 104 connects with both first-gate-runner-metal 102 and second-gate-runner-metal 103.

To illustrate with more details, please refer to FIG. 2A and FIG. 2B for top view of the trench MOSFET disclosed in FIG. 1 near termination area 101 (circled by solid line in FIG. 1) and near the second-gate-runner-metal 103 (circled by dotted line in FIG. 1), respectively. In FIG. 2A, in active area, a plurality of gate trenches 105 are horizontally arranged, source regions and body regions of the trench MOSFET are connected to source metal 110 via trenched source-body contact 106 and trenched body contact 108, which can be seen more clearly in FIG. 2C of a A-B-C-D-E cross section of FIG. 2A. Trenched gate contact 107 is extending into gate contact trench 109 and contacting with the first-gate-runner-metal 102 which also served as metal field plate for termination area 101.

In FIG. 2B, the gate trenches of stripe cell structures are symmetrically distributed on both sides of the second-gate-runner metal 103 and share the same gate contact trench 109 and trenched gate contact 107.

As mentioned above, the conventional trench MOSFET layout as shown in FIG. 1 has gate trenches of stripe cell structures in one direction (horizontal direction or vertical direction), causing high stress on die after the gate trenches are padded with gate oxide and filled with doped poly-silicon. The stress effect becomes more pronounced when the gate trenches are deep or die size is big. The total die stress transfers to wafer, resulting in wafer warpage issue so that the wafer can not be further processed after doped poly-silicon deposition. Moreover, the die stress also causes reliability failure.

Accordingly, it would be desirable to provide a new and improved semiconductor power device layout to avoid the constraint discussed above.

### SUMMARY OF THE INVENTION

The present invention has been conceived to solve the above-described problems with the related art, and it is an object of the invention to provide a device layout in which horizontal gate trenches and vertical gate trenches are alternatively arranged in single device (one or two directions) to balance out the stress caused from one direction. At the same time, gate connection trench is provided to reduce gate resistance Rg when gate trench length is long.

In one aspect, the present invention features a semiconductor power device layout having stripe cell structures comprising: a plurality of horizontal gate trenches; and a plurality of vertical gate trenches in single device.

Preferred embodiments include one or more of the following features. The horizontal gate trenches and the vertical gate trenches are alternatively arranged in horizontal or vertical direction for stress reduction. The horizontal gate trenches and the vertical gate trenches are alternatively arranged in both horizontal and vertical direction for further stress reduction. Gate connection trenches are provided to connect said vertical trenches along horizontal direction to reduce gate resistance Rg of vertical trenches.

In the said above, the description has been directed to Trench MOSFET. Moreover, this invention is also applicable to a trench IGBT with gate trenches, and super-junction MOSFET with deep trenches filled with a dielectric layer or poly-silicon padded with a dielectric layer or epitaxial layer for formation of a super-junction structure as disclosed in prior arts of U.S. Pat. Nos. 6,740,931, 7,364,994, 7410,891 and 7,109,110.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a trench MOSFET layout with stripe cell structures of prior art.

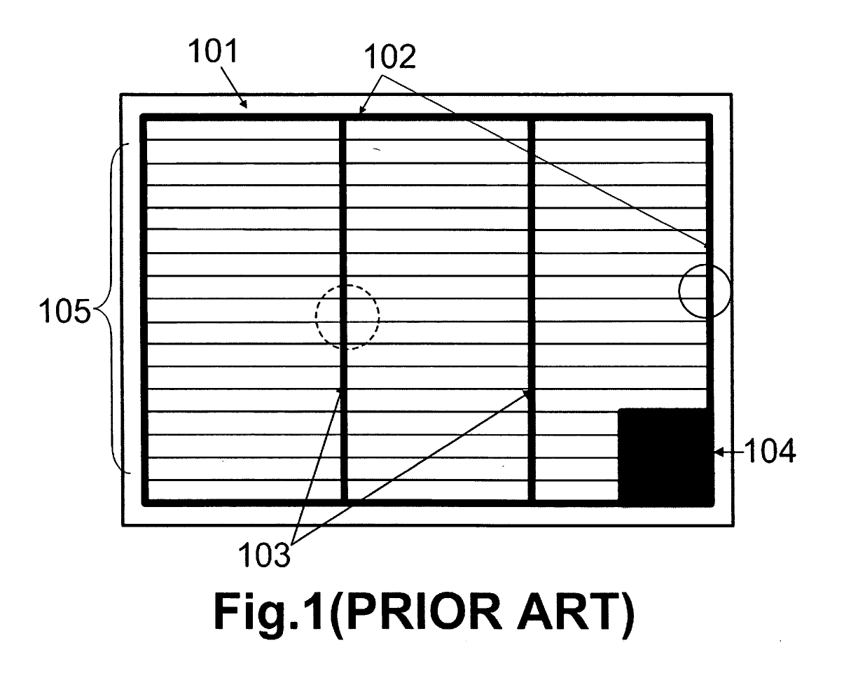

FIG. 2A is top view of area circled by solid line in FIG. 1.

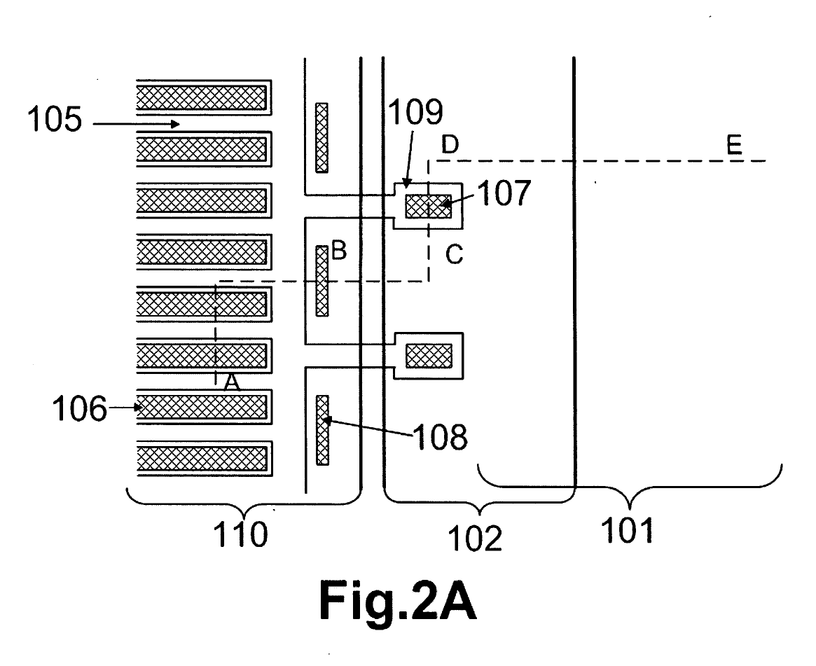

FIG. 2B is top view of area circled by dotted line in FIG. 1.

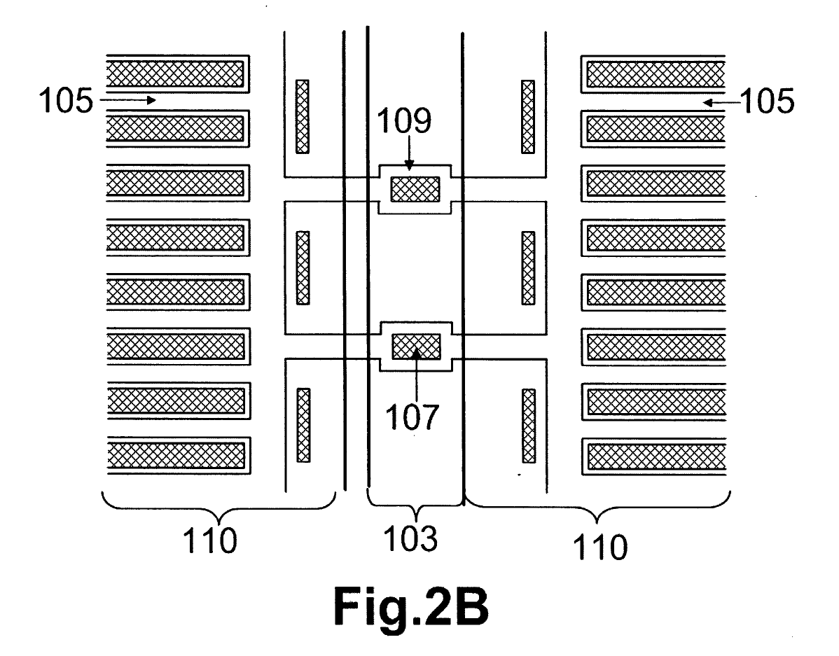

FIG. 2C is A-B-C-D-E cross-sectional view of FIG. 2A.

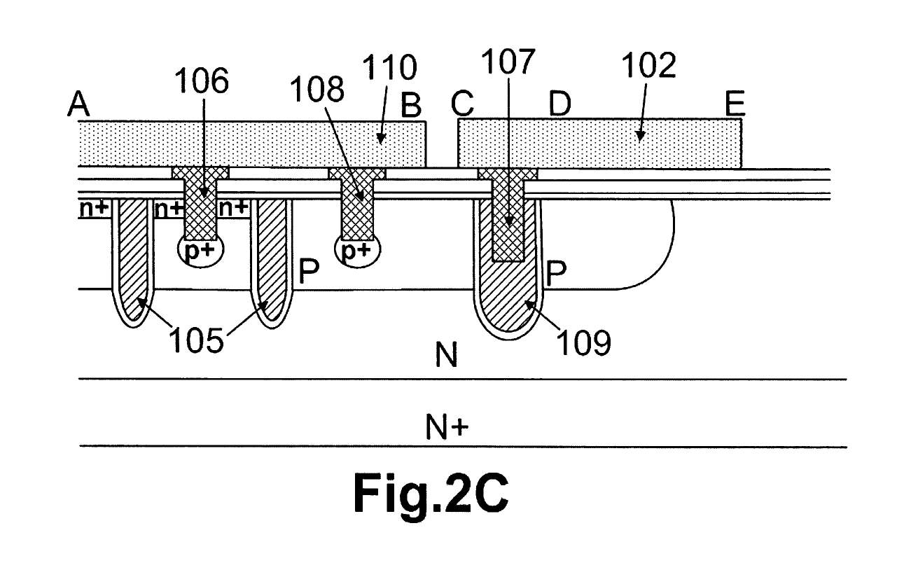

FIG. 3 is a trench MOSFET layout of a preferred embodiment according to the present invention.

FIG. 4A is a trench MOSFET layout of another preferred embodiment according to the present invention.

FIG. 4B is top view of area circled by dotted line in FIG. 4A.

FIG. 5 is a trench MOSFET layout of another preferred embodiment according to the present invention.

### DETAILED DESCRIPTION OF THE EMBODIMENTS

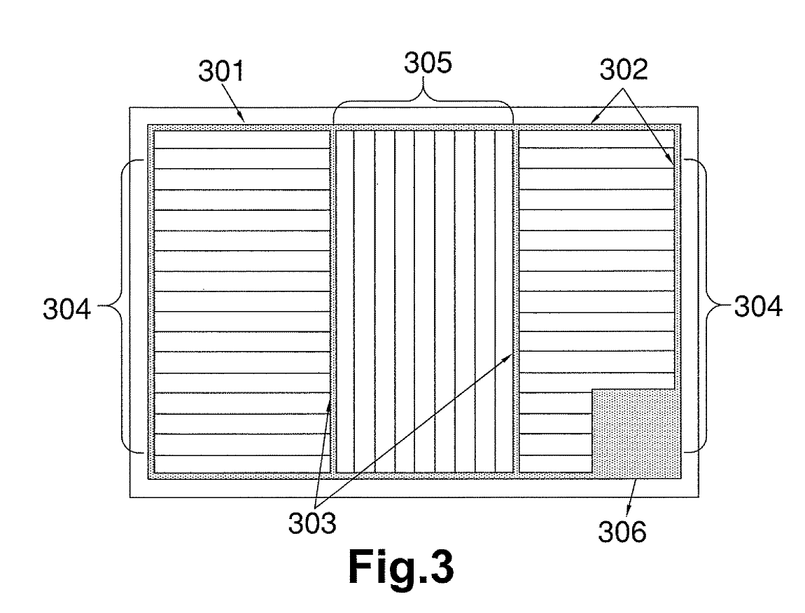

Please refer to FIG. 3 for a trench MOSFET layout of a preferred embodiment. A plurality of horizontal gate trenches 304 and a plurality of vertical gate trenches 305 are alternatively arranged in horizontal direction. Termination area 301 is formed around the whole device configuration with first-gate-runner-metal 302 nearby serving as metal field plate. Second-gate-runner-metal 303 is formed along vertical direction, while gate pad 306 connects with both the first-gate-runner-metal 302 and the second-gate-runner-metal 303.

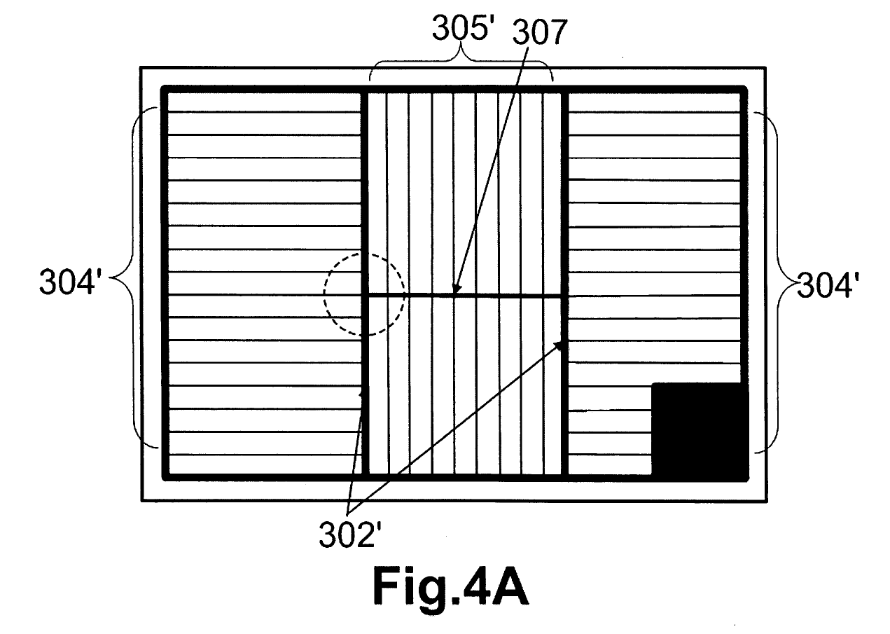

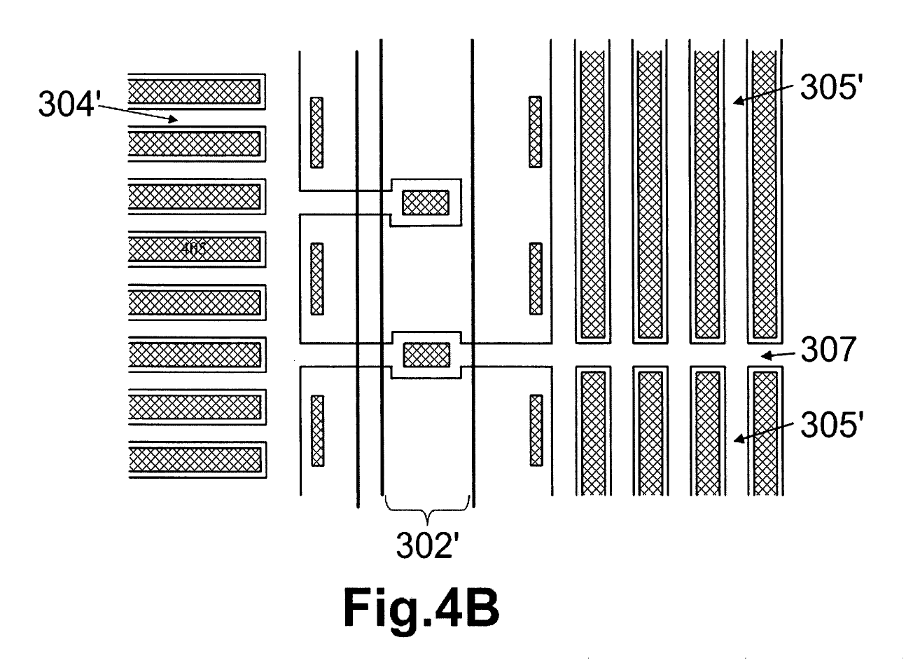

Please refer to FIG. 4A for a trench MOSFET layout of another preferred embodiment which has a similar structure to FIG. 3 except that, a gate connection trench 307 is provided to connect the vertical gate trenches 305′ array along horizontal direction between second-gate-runner-metal 302′ to reduce gate resistance Rg of vertical gate trenches when gate trench length is long.

FIG. 4B shows a top view of area circled by dotted line in FIG. 4A. On one side of the second-gate-runner-metal 302′, the gate connection trench 307 is connected to the vertical gate trenches 305′ along horizontal direction while the horizontal gate trenches 304′ are extending on the other side of the second-gate-runner-metal 302′.

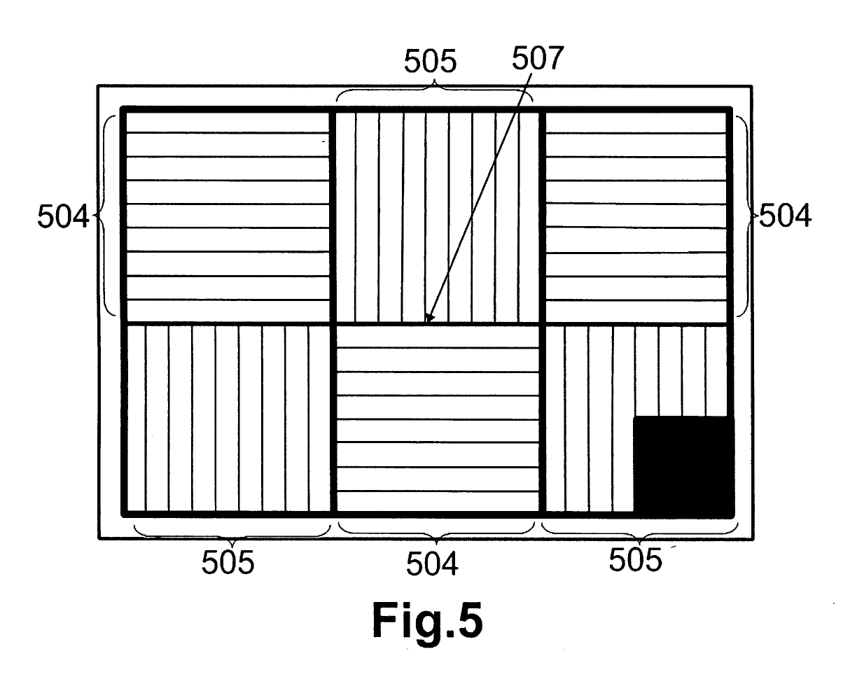

Please refer to FIG. 5 for a trench MOSFET layout of another embodiment. A plurality of horizontal gate trenches 504 and a plurality of vertical gate trenches 505 are alternatively arranged in both horizontal and vertical direction for further stress reduction, and a gate connection trench 507 connecting with said vertical gate trenches 505bis provided to reduce gate resistance Rg when trench length is long.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A semiconductor power device comprising:
a plurality of horizontal trenches; and
a plurality of vertical trenches.

2. The semiconductor power device of claim 1, wherein said horizontal trenches and vertical trenches are alternatively arranged in horizontal direction or vertical direction.

3. The semiconductor power device of claim 1, wherein said horizontal trenches and vertical trenches are alternatively arranged in both horizontal and vertical directions.

4. The semiconductor power device of claim 1 is trench MOSFET, wherein said horizontal and vertical trenches are filled with doped poly-silicon padded with gate oxide as trenched gates.

5. The semiconductor power device of claim 1 is trench IGBT, wherein said horizontal and vertical trenches are filled with doped poly-silicon padded with gate oxide as trenched gate.

6. The semiconductor power device of claims 4 and 5 further comprises gate connection trenches connect to said vertical and/or said horizontal trenches.

7. The semiconductor power device of claim 1 is super-junction MOSFET, wherein said horizontal and vertical trenches are filled with a dielectric layer, or poly-silicon padded with a dielectric layer or an epitaxial layer for super-junction formation.
